(19) United States
(12) Patent Application Publication
(10) Pub. No.: US 2013/0329379 A1
(43) Pub. Date: Dec. 12, 2013

(54) SWITCHING DEVICE FOR SUPPLYING HIGH-ENERGY FUNCTIONAL COMPONENTS

(71) Applicants: Maik Hohmann, Holzkirchen (DE); Frank Schumann, Sauerlach (DE); Reinhard Niejodek, Muenchen (DE)

(72) Inventors: Maik Hohmann, Holzkirchen (DE); Frank Schumann, Sauerlach (DE); Reinhard Niejodek, Muenchen (DE)

(73) Assignee: TRANSTECHNIK GMBH & CO. KG, Holzkirchen (DE)

(21) Appl. No.: 13/984,504

(22) PCT Filed: Dec. 23, 2011
(86) PCT No.: PCT/EP11/06542

§ 371 Date: Aug. 8, 2013

(30) Foreign Application Priority Data
Feb. 15, 2011 (DE) 10 2011 011 305.3

(51) Int. Cl. H05K 7/14

(52) U.S. Cl. CPC H05K 7/1427
USPC 361/736

(57) ABSTRACT

A high-voltage switching device (1) is described with a charge storage arrangement (3) with a multiplicity of charge storage modules (M1, M2, M3, M4, . . . , MN) connected in series, wherein in each case a certain number of the charge storage modules (M1, M2, M3, M4, . . . , MN) are arranged in a common assembly housing (21, 30, 50) so as to form a charge storage module assembly (B), and wherein the assembly housings (21, 30, 50) are mounted in a supporting frame in an insulated manner.

The invention concerns a high-voltage switching device, in particular for the supply of a high-energy functional component with high-voltage pulses, with a charge storage arrangement with a multiplicity of charge storage modules connected in series.

For many experiments in high-energy physics particle accelerators, such as, for example, storage rings, are necessary, in which elementary particles are brought by means of acceleration up to high energies (in part up to a velocity near that of light). Here the energy of these articles can lie in the GeV or TeV range. For the construction of such particle accelerators various high-energy functional components are required, in order to accelerate the particles to a sufficiently high-velocity in the desired direction. These high-energy functional components include klystrons, with the aid of which, inter alia, microwaves are generated; these are deployed for purposes of accelerating particles in cyclotrons or linear accelerators. For the operation of a klystron short voltage pulses of between 20 and approx. 120 kV, with currents of 10 to approx. 50 A, are currently required. To this end sufficiently high-power pulses of approx. 100 kV or more are normally generated in special high-voltage switching devices from an input voltage of approx.10 kV with the aid of a transformer. These high-voltage switching devices are constructed with a multiplicity of subassemblies, which are required, amongst other functions, for the formation of the requisite output pulse. To this end the build is matched to the klystron in question, and the pulse repeat time, pulse height, and pulse shape, particularly required by the latter. Furthermore such high-voltage switching devices are relatively expensive. Further high-energy functional components deployed in large particle accelerators are so-called “kicker magnets”; these are used to kick the accelerated particles out of a particle stream and thus, for instance, to deflect them into another accelerator. These kicker magnets also require very high and short voltage pulses, for the generation of which relatively expensive circuitry is currently deployed. In the context of the present invention a “high-energy functional component” is to be understood to include, in particular, such functional components as are, for example, required in high-energy physics laboratories, such as the above mentioned particle accelerators, and which require an appropriately pulsed high-voltage supply with voltages of preferably more than 12 kV. These include thus the kicker magnets mentioned, or klystrons, or such devices containing functional components for purposes of accelerating particles in the high-energy physics sector. However, it is expressly emphasised that an inventively controlled klystron can also be deployed for other purposes, in which appropriate high-frequency signals are required.

A high-voltage switching device that is particularly advantageous for these purposes is, for example, described in WO 2010/108524 (DE 10 2009 025 030 A1). This high-voltage switching device works with a charge storage arrangement consisting of a multiplicity of charge storage modules connected in series. The charge storage arrangement is connected via at least one first switch with two input terminals, i.e. the chain of charge storage modules is at one end, for example, connected via the first switch with the first input terminal, and at the other end with the second input terminal. Correspondingly the charge storage arrangement is connected via at least one second switch with two output terminals, i.e. at one end, for example, via the second switch with a first output terminal, and at the other end with the second output terminal. In operation an input voltage is present at the input terminals, and the output terminals are connected with high-voltage terminal contacts of the high-energy functional components.

By means of a control device the individual charge storage modules and the first and second switches are controlled such that in a charging phase the charge storage modules are connected successively either individually or as a group in series with a charging voltage. In the discharging phase the first switch is then opened, i.e. the charge storage arrangement is disconnected from the input voltage, and by closing the second switch the charge storage modules are connected with the high-voltage terminal contacts of the high-energy functional component, and can thus be discharged with the delivery of a voltage pulse onto the high-energy functional component. Since, as described above, the output pulses have voltages of 100 kV and more and at the same time considerable currents, the construction of such a high-voltage switching device is automatically linked with problems of insulation. This affects in particular the charge storage arrangement, in which the high-voltage is built up during the charging phase. In the course of discharge pulses of more than 100 kV with rise times of 5 μsecs are to be generated. At the same time displacement charges arise, which generate ionisations, which in turn in the event of separation distances of significantly less than 1 mm/kV can also lead to a flashover. The overall build of the high-voltage switching device, in particular of the charge storage arrangement, must therefore be undertaken such that a high dielectric strength, a high level of operational reliability, and in particular also a high level of safety for personnel located in the vicinity of the build are ensured. Then again in physics laboratories in particular the surface areas are relatively limited, so that it is important that the overall build is compact and nevertheless has good access for repairs.

It is therefore an object of the present invention to specify an improved high-voltage switching device, which on the one hand fulfils the above requirements and on the other hand is as adaptable as possible to various customer requirements in a cost-effective and variable manner.

This object is achieved by means of the high-voltage switching device in accordance with claim 1.

The inventive high-voltage switching device has, as mentioned in the introduction, a charge storage arrangement with a multiplicity of charge storage modules connected in series. Here in accordance with the invention a certain number of these charge storage modules connected in series always form a charge storage module assembly and are accommodated in a common assembly housing. These assembly housings are in each case mounted in an insulated manner in a supporting frame; this can, for example, be implemented in that the assembly housings are themselves designed as an insulating assembly housing, i.e. they are at least partly produced from a non-conducting material such as, for example, plastic, and/or in that the assembly housings are mounted in the supporting frame with insulating mounting elements, such as rails or similar.

As a result of the inventive arrangement of the charge storage modules in charge storage module subassemblies on the one hand a particularly cost-effective manufacture of the charge storage modules is possible. In particular certain controller components that are necessary for the operation of the charge storage modules can be used jointly with the charge storage modules of a assembly. Moreover in this manner control lines to the individual charge storage modules can be eliminated, or the control data transfer can possibly be reduced onto a commonly used databus. On the other hand by the accommodation of the individual charge storage module subassemblies in separate assembly housings and their insulated mounting in a supporting frame, the charge storage modules as a whole can be packed relatively densely, without the fear of voltage flashovers between the charge storage modules and/or to the supporting frame or other components, so that a compact overall structure can be implemented in a simple and cost-effective manner.

Accordingly the conditions stipulated with regard to safety, flexibility and cost efficiency can be well fulfilled collectively by the inventive build and insulation concept.

The dependent claims and the following description contain particularly advantageous further developments and configurations of the invention.

Such a assembly housing preferably has a conducting structure enclosing the charge storage module assembly as a Faraday cage. This has the advantage that the charge storage modules together with their components are screened by means of this Faraday cage. This is particularly important since many components such as cooling bodies, capacitors, etc, but also conducting tracks of the charge storage modules, have sharp corners and edges, which in operation at times are suddenly at very high potential and on which correspondingly very high charge peaks form, which can lead to a charge flashover with corresponding damage to the electronics. This conducting structure is preferably designed such that it itself has no sharp corners and edges, but if need be has extensively rounded corners and edges.

The switching device is built such that each charge storage module per se, each charge storage module assembly, and also the overall charge storage arrangement, are of a 2-pole design. To this end the charge storage module subassemblies are interconnected such that the series connection of the charge storage modules is continued between the charge storage module subassemblies, which means that the last of the charge storage modules in one charge storage module assembly is electrically connected with the first charge storage module of an adjacent charge storage module assembly.

Here a charge storage module assembly is preferably electrically connected in each case with the conducting structure of the related assembly housing. For example, for this purpose in each case one of the two poles of a charge storage module assembly can preferably be electrically connected with the conducting structure of the related assembly housing. The overall charge storage module assembly thereby finds itself in operation at a fluctuating potential, however the electronics within the assembly are protected by the Faraday effect, since indeed no greater potential difference can occur between the components and the surrounding conducting structure than that between the two poles of the charge storage module assembly. The conducting structure of the assembly housing is very particularly preferably electrically connected preferably with a contact point of the charge storage module assembly, which lies at an average potential within the charge storage module assembly, preferably with a contact point between two modules that are average in terms of the potential distribution. In this case the maximum potential difference between the components of the charge storage module assembly and the surrounding assembly housing lies below the maximum potential difference present between the two poles of the charge storage module assembly, for example, at only half of the maximum potential difference.

Moreover such a assembly housing preferably has an insulating layer on an outer face of the housing and/or on an inner face of the housing. An insulating layer increases the dielectric strength considerably, which is both of advantage in the interior of the assembly housing, so as better to protect the components of the electronics, and also externally, so as to be able to arrange adjacent charge storage module subassemblies closer together, without resulting in charge flashovers. Moreover it is possible to mount the charge storage module subassemblies, for example, only on insulating rails at the edge of the supporting frame in an insulating manner, instead of utilising robust shelves in the form of a rack produced from a highly insulating material. By this means the production resource and costs can be held lower and a non-beneficial influence on the field distribution between the assembly housings caused by rack shelving is avoided.

A housing build with a conducting structure so as to form a Faraday cage and insulating layers on the inner and/or outer face can be implemented in a particularly simple manner, for example, in that the assembly housing has at least one inner housing part, and one outer housing part at least partly enclosing the inner housing part, so as to form a multi-layer housing. The inner housing part can particularly preferably consist of an insulating material, which on its outer face is coated with a metallisation, and this inner housing part can then be surrounded by an outer housing part also produced from an insulating material, so that the overall assembly housing wall is constructed as a form of sandwich structure with an inner and an outer insulating layer and a metal structure located in between. To this end the outer housing part can, for example, be constructed in two parts, and the inner housing part (which can also be constructed in two parts) is inserted into the one part of the outer housing part, which is then closed by the other part.

On edges and corners present on at least one outer face of a assembly housing, for example in a build with an inner and an outer housing part, the corners and edges of the outer housing part are preferably rounded. The rounding radius is preferably at least 10 mm, particularly preferably at least 14 mm. In the same manner any openings, cut-outs, slots, etc in the housing are also preferably rounded. As a result of the rounding of the housing edges, etc the field distribution between adjacent assembly housings and also between the assembly housings and adjacent parts of the supporting frame, is improved such that no excessive voltage peaks occur. Consequently the dielectric strength of the overall structure is further increased by this measure.

Furthermore it is preferable for the charge storage modules of one charge storage module assembly to be arranged on a common assembly carrier, for example, a printed circuit board of the assembly. By this means considerable cost savings are possible, since wiring connections between the individual charge storage modules of one charge storage module assembly, for example, within the insulating assembly housing, are no longer necessary. In particular by this means the plug-in connections that are particularly susceptible to faults can be reduced to a minimum.

The charge storage module subassemblies are preferably arranged in the form of a matrix in rows and columns in the supporting frame, wherein a number of charge storage module subassemblies are arranged adjacent to one another in one row in the supporting frame and are electrically interconnected. Here there are preferably just two or three columns of charge storage module subassemblies in the supporting frame, i.e. just two or three charge storage module subassemblies are arranged in a row. Here the electrical connection from one row to an adjacently arranged row of charge storage module subassemblies is particularly preferably made in one of the columns between two charge storage module subassemblies arranged directly adjacent to one another, i.e. the connection is made from one of the two charge storage module subassemblies arranged in a row to the charge storage module assembly of the neighbouring row arranged in the same column. In other words the interconnections between the charge storage module subassemblies within the charge storage arrangement in the case of this preferred interconnection arrangement are made in a serpentine pattern, wherein the column is changed in each row. By this preferred special arrangement and the serpentine interconnection of the charge storage module subassemblies the maximum voltage between adjacent charge storage module subassemblies can be limited to a relatively low value and the electrical connections of the charge storage modules can be implemented in terms of relatively short cables. However, depending on the voltages specifically required, a zigzag form of connection, in each case of the last charge storage module assembly of a row to the first charge storage module assembly of a neighbouring row, would also be possible in principle.

As mentioned above, the charge storage module subassemblies of a 2-pole design are interconnected such that the series connection of the charge storage modules is continued between the charge storage module subassemblies. Here the charge storage modules are preferably arranged in the charge storage module subassemblies, and the charge storage module subassemblies are also preferably arranged in the supporting frame relative to one another, and are electrically interconnected such that the charge storage modules are connected with one another along the shortest path in accordance with their series connections in the charge storage arrangement. That is to say, the sorting of the charge storage module subassemblies and their orientation relative to one another in the supporting frame is undertaken such that in the adjacent and interconnected charge storage module subassemblies the charge storage modules that are directly connected with one another are located spatially nearest side-by-side. This applies both in the case of a connection between two adjacent charge storage module subassemblies in one row, and also in the case of a transition from one row into the next row.

The structure is particularly preferably such that the rows are arranged one above another in the supporting frame, i.e. such that the columns of the structure run vertically and accordingly the electrical connections between the charge storage module subassemblies run in a serpentine pattern from bottom to top (or vice versa) through the rows in the supporting frame. The advantage of such a vertical arrangement of the columns in the supporting frame consists in the fact that the supply lines to the charge storage arrangement, i.e. the overall high-voltage switching arrangement, can be led from below and above. This is beneficial inasmuch as in most physics laboratories, with respect to the freedom of movement for the personnel, separate and insulated cavities for supply lines are in any event present in the ceiling and the floor. The interconnection of the high-voltage switching arrangement, i.e. the charge storage arrangement is particularly preferably undertaken such that in the lowest row the first charge storage module assembly is connected to a ground potential and the output of the highest charge storage module assembly lies at the desired high voltage level.

In principle, however, it is also possible to select the overall build such that the orientation of the columns runs horizontally. In particular a plurality of such charge storage arrangements could then be arranged one above another in one or a plurality of supporting frames. This lends itself, conditions permitting, if a plurality of such charge storage arrangements are to be connected in parallel, with in each case a multiplicity of charge storage modules connected in series, as is designed to take place, for example, in a preferred example of embodiment of WO 2010/108524 A1 (described, for example, with the aid of FIGS. 5 to 7), wherein, however, a vertical orientation of the columns can be advantageous in such a variant of embodiment. This depends, as a rule, on the local circumstances on site.

The charge storage modules can in principle be designed with different capacities for storage of the charge. As a rule the charge storage is implemented in terms of one or a plurality of capacitances in the charge storage module, interconnected in a suitable manner. A charge storage module is preferably designed such that in operation a maximum voltage difference of 2 kV, preferably a maximum of 1 kV, is present between its two poles. Such charge storage modules can be manufactured from conventional components and are thus relatively cost-effective.

Here it is particularly preferable for a charge storage module assembly to comprise a maximum of eight charge storage modules, very particularly preferably a maximum of four. In a preferred form of embodiment this means that the voltage across the two poles of a charge storage module assembly is a maximum of 16 kV, particularly preferably a maximum of 8 kV, and very particularly preferably a maximum of 4 kV. In the above described preferred build of the assembly housing with a conducting structure electrically connected with one of the poles, which surrounds the whole of the electronics of the charge storage module assembly, it is thus ensured that between the components of the charge storage modules and the environment a maximum corresponding voltage of 16 kV, or 8 kV, or 4 kV can be applied, as a result of which destruction of even the more sensitive components is not to be feared.

In the preferred structure with two charge storage module subassemblies arranged side-by-side in a row, and the serpentine interconnection of the subassemblies, when using charge storage module subassemblies with a maximum pole voltage of 4 kV, the maximum voltage between two adjacent charge storage module subassemblies can moreover be 16 kV. With the use of suitable insulated assembly housings, made for example from polyurethane or polyethylene, as well as an insulated mounting of the insulated assembly housings in the supporting frame by means of rails, also made from polyurethane or polyethylene, for example, a separation distance of just 20 mm between the charge storage module subassemblies of two adjacent rows is therefore necessary so as to achieve the required dielectric strength. This allows a particularly compact build for the overall high-voltage switching device.

The charge storage module subassemblies and their assembly housings are in each case preferably constructed such that contact can be made with them exclusively from the front, and such that for maintenance or repair they can be simply removed from and/or inserted into the supporting frame.

The high-voltage switching device particularly preferably has a housing surrounding at least the charge storage arrangement, which is built in a sandwich form of construction with electrically insulating layers and electrically conducting layers. In such a sandwich form of construction, by suitable interconnection of the electrically conducting layers with the electrically insulating layers in each case arranged in between, a plurality of Faraday cages can be implemented within one another. Here the electrically conducting layers are more advantageously electrically interconnected and connected to a ground potential.

The insulating layers can, for example, be separate material layers made from insulating substances such as plastic. However, they can also take the form of coatings of the metal parts, for example, metal sheets with a suitable insulating plastic such as PE. In one preferred example of embodiment an insulating layer is embodied as an air layer, or an evacuated layer.

The housing can preferably be arranged in or on the supporting frame, i.e. the supporting frame is, for example, designed as a conventional rack, wherein a rack with the typical standard dimensions is preferably selected for the insertion of e.g. 19″ standard housings. Accordingly the insulated assembly housings are preferably embodied as 19″ housings.

Care should advantageously be taken to ensure that the rails within the rack, which serve to provide the mountings for the insulating assembly housings, also consist of an insulating substance, preferably plastic. Externally this rack can then be clad in a housing. In principle, however, it is also possible that the housing itself forms the supporting frame, i.e. that no separate frame is present, but , for example, the mounting strips by means of which the assembly housings are mounted, are arranged directly on the walls of the housing. Likewise the housing can also be designed such that it encloses the supporting frame as a separate external shell spaced apart from the supporting frame.

Also the supporting frame, possibly the rails, and/or the housing of the charge storage arrangement, are preferably designed such that the corners and edges—at least the corners and edges, or all corners and edges pointing towards the assembly housing lying at a high potential—are rounded, and particularly preferably have the above-specified minimum radius.

Not only is the charge storage arrangement particularly preferably arranged within the housing, but also further components of the high-voltage switching device, in particular the switches and also, if necessary, the controller to control these switches and the individual charge storage modules.

In one preferred example of embodiment the housing, which, for example, is sealed relative to the environment, is filled with a fluid, preferably a gas, which—compared with ambient air at standard conditions—has an increased dielectric strength. The dielectric strength is preferably more than 2 kV/mm, particularly preferably more than 4 kV/mm. In the simplest case this gas can take the form, for example, of filtered and/or dried air. If a particularly high dielectric strength is required, an insulating gas, for example an inert gas such as nitrogen or a noble gas, e.g. helium or argon, can be used as the charge.

By means of suitable ventilating fans the fluid, in particular, the gas, can be circulated in the housing. Cooling is possible with the aid of one or a plurality of heat exchangers arranged in the housing at suitable positions. By the use of a fluid charge with a high dielectric strength a kind of “self-healing” insulation system is created, since ionising field strength peaks can be washed out or blown away by the fluid flowing past.

In what follows the invention is elucidated once again with the aid of examples of embodiment with reference to the accompanying figures. In the various figures the same components are provided with the same reference symbols in each case. Here:

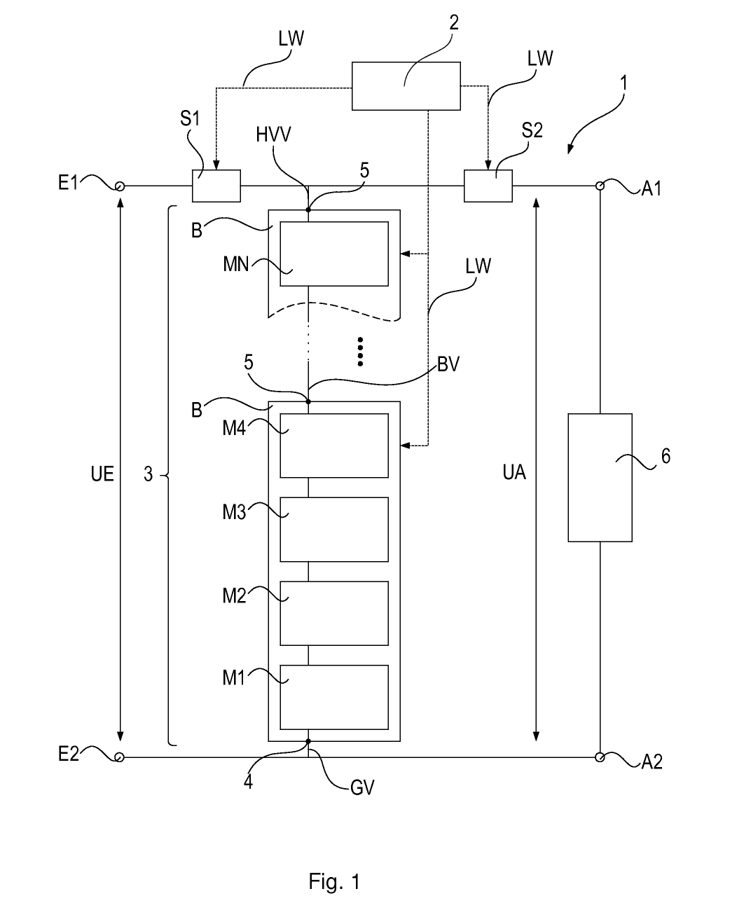

FIG. 1 shows a simplified schematic circuit diagram of an example of embodiment of an inventive high-voltage switching device for the control of a klystron,

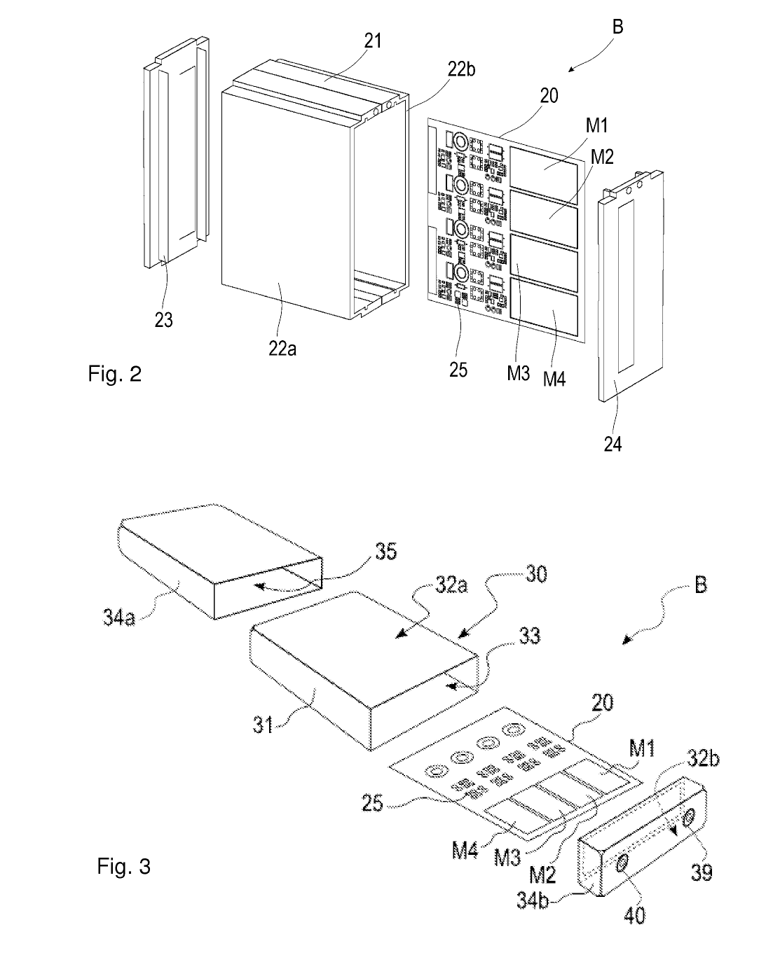

FIG. 2 shows in perspective an exploded view of an example of embodiment of an inventive charge storage module assembly with a first example of embodiment of a assembly housing,

FIG. 3 shows in perspective an exploded view of an example of embodiment of an inventive charge storage module assembly with a second example of embodiment of a assembly housing,

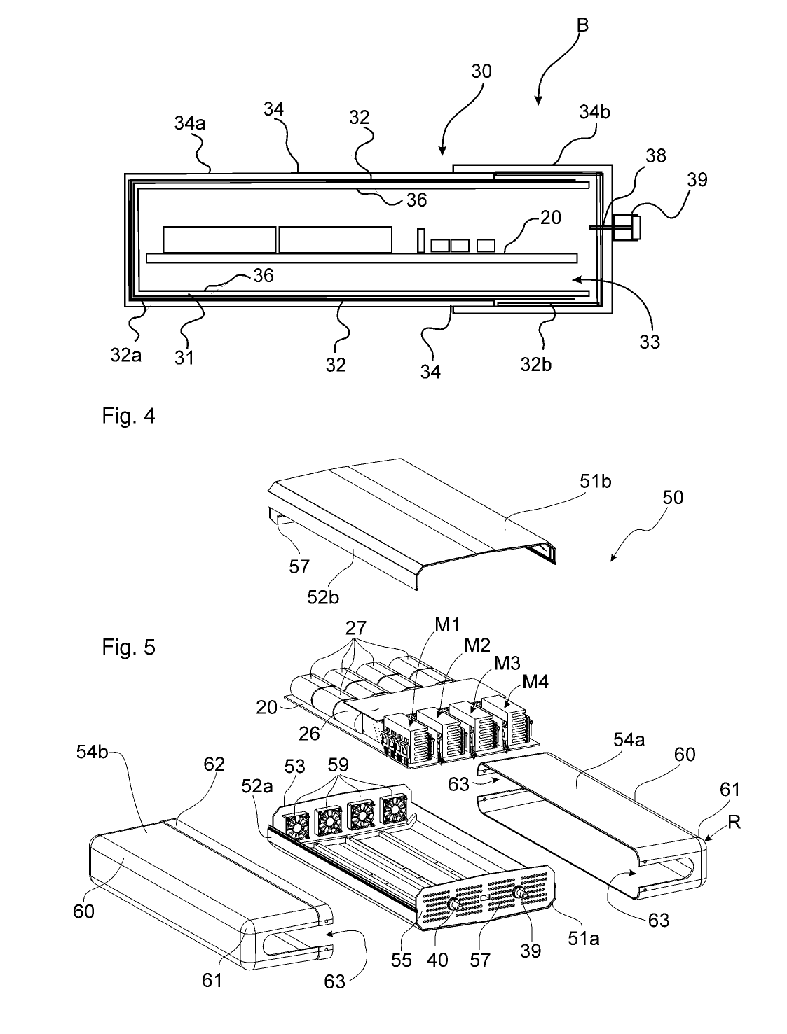

FIG. 4 shows a schematic longitudinal section through the assembly housing in FIG. 3,

FIG. 5 shows in perspective an exploded view of an example of embodiment of an inventive charge storage module assembly with a third example of embodiment of a assembly housing.

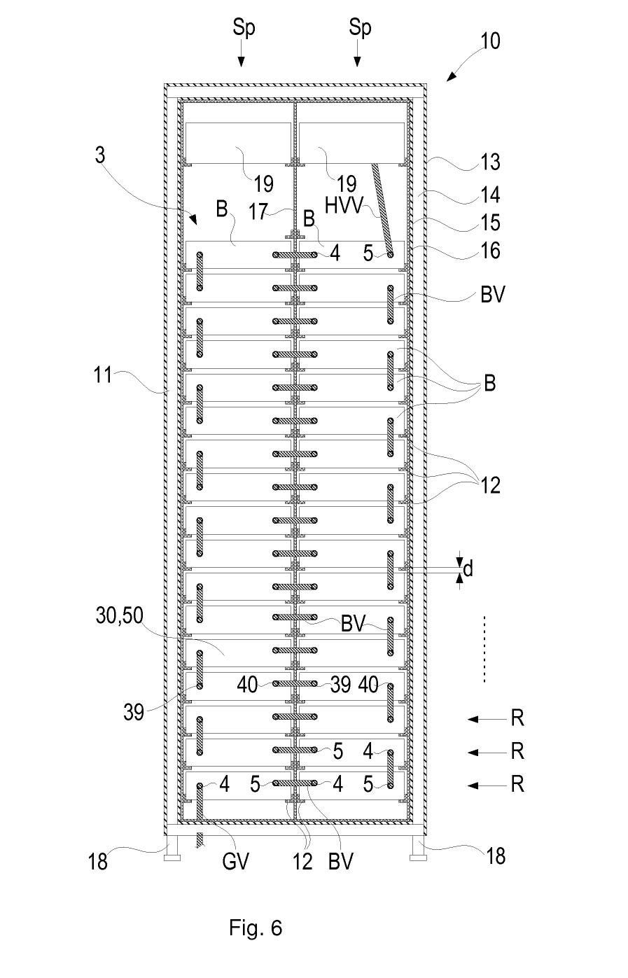

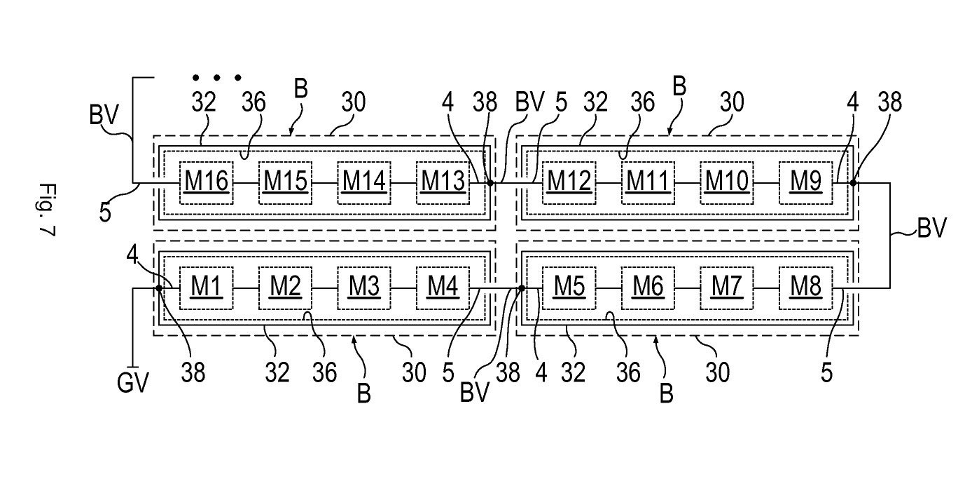

FIG. 6 shows a section through a supporting frame provided with a housing (as seen from the front face outwards) with therein arranged and electrically connected charge storage module subassemblies of an example of embodiment of an inventive charge storage arrangement,

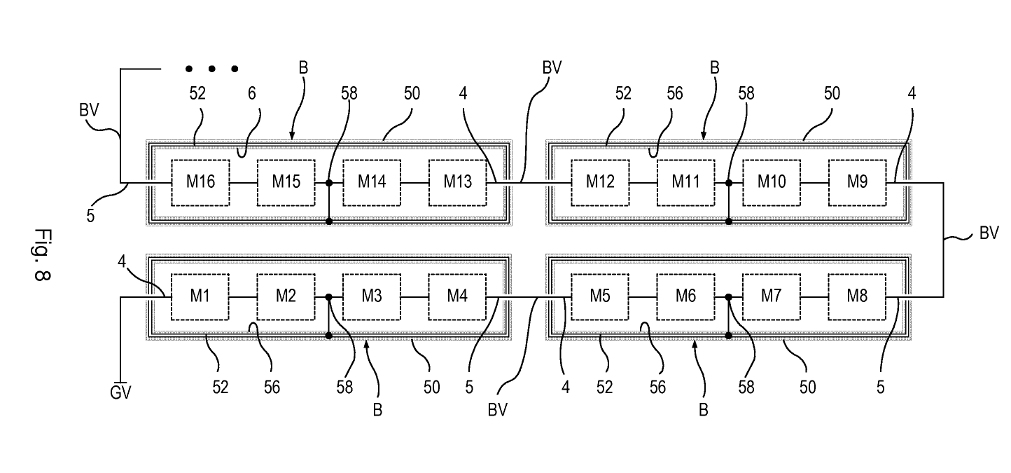

FIG. 7 shows a schematic arrangement of a first example of embodiment of an electrical series connection of the charge storage module subassemblies, which are located in each case in a assembly housing,

FIG. 8 shows a schematic arrangement of a second example of embodiment of an electrical series connection of the charge storage module subassemblies, which are located in each case in a assembly housing.

In FIG. 1 a klystron 6 is connected to the output terminals A1, A2 of the high-voltage switching device 1; here the klystron 6 is only represented in a simplified manner as a block. The core item of this high-voltage switching device 1 is a charge storage arrangement 3 with a multiplicity of charge storage modules M1, M2, M3, M4, . . . , MN connected in series. These charge storage modules M1, M2, M3, M4, . . . , MN are in each case of a 2-pole design; they can be charged and discharged in a managed manner. For this purpose each charge storage module M1, M2, M3, M4, . . . , MN is equipped with a capacitance, or a capacitance arrangement, as well as with its own electronic module controller, which can be controlled by a control device 2. To this end the charge storage modules M1, M2, M3, M4, . . . , MN are connected with the control device 2 via optical waveguides LW for the transmission of control signals, wherein each optical waveguide connection runs to a charge storage module assembly B, and, as described in what follows, the control signals are internally distributed to the charge storage modules.

The overall charge storage arrangement 3 thus once again forms a 2-pole design, wherein one of the poles 5 is connected via a high-voltage connection HW via a first switch S1 with an input terminal E1, and via a second switch S2 with one of the output terminals A1 of the high-voltage switching device 1. The other pole 4 of the charge storage arrangement 3 is connected via a ground connection GV. on the one hand with a second input terminal E2. and on the other hand with a second output terminal A2 of the high-voltage switching device 1; these are, for example, also located at an electrical ground potential.

An input voltage UE can be applied between the two input terminals E1, E2; in a charging phase this is so as to connect the charge storage modules M1, M2, M3, M4, . . . , MN successively either individually or as a group in series with a charging voltage by closing the switch S1 (with the switch S2 open). To this end not only the individual charge storage modules M1, M2, M3, M4, . . . , MN, but also the first switch S1 and the second switch S2 are switched in a coordinated manner via light waveguides LW by the control device 2. In a discharging phase the first switch S1 is then opened and the second switch S2 is closed, so that the charge storage modules M1, M2, M3, M4, . . . , MN are disconnected from the charging voltage, i.e. the input voltage UE; instead the voltage is fully applied via the two poles 4, 5 of the charge storage arrangement 3 across the output terminals A1, A2 of the high-voltage switching device, so that at least a proportion of the charge storage modules M1, M2, M3, M4, . . . , MN are discharged, with the delivery of a voltage pulse onto the high-energy functional component 6, i.e. in this case the klystron 6.

The charge storage arrangement 3 can in principle have a chain of charge storage modules M1, M2, M3, M4, . . . , MN, of any length, i.e. any number of charge storage modules M1, M2, M3, M4, . . . , MN, connected one behind another, preferably a multiple of four, for example, 128 charge storage modules. If, for example, each of the charge storage modules M1, M2, M3, M4, . . . , MN is able to store a voltage of e.g. 1 kV , then at the two poles 4, 5 of the charge storage arrangement 3 an overall pulse of, e.g. 128 kV, can be delivered to the klystron 6.

In addition to the components represented the inventive high-voltage switching device 1 can also have a multiplicity of further components or subcomponents, which are not individually represented here. The exact build of the charge storage modules M1, M2, M3, M4, . . . MN and also the further components of the high-voltage switching device and their interaction can, for example, be found in WO 2010/108524 A1, to the full contents of which reference is made here. At the same time it is also possible to build all the examples of embodiment cited there in the inventive manner described here.

An important feature of the inventive structure consists in the fact that the charge storage modules M1, M2, M3, M4, . . . , MN are combined into charge storage modules subassemblies B. In the examples of embodiment shown in FIGS. 1 to 6 exactly four of the charge storage modules M1, M2, M3, M4, . . . , MN are combined in each case into a charge storage module assembly B, as represented for the charge storage modules M1, M2, M3, M4 in FIG. 1. As a result of the series connections within the charge storage module subassemblies B these charge storage module subassemblies B are also once again of a 2-pole design (in each case with two poles 4 and 5), wherein two charge storage module subassemblies B, connected in series by means of assembly connections BV in each case between a pole 5 of the one charge storage module assembly B, and an adjacent pole 4 of the next charge storage module assembly B, are electrically interconnected. This assembly connection BV preferably takes the form, as in the case of the ground connection GV and the high-voltage connection HVV, of (multiply) insulated high-voltage cables.

In FIG. 2 the build of a charge storage module assembly B is represented in more detail. Here the individual charge storage modules M1, M2, M3, M4 are implemented on a common printed circuit board 20. Such a board 20 has only one light waveguide terminal for all four charge storage modules M1, M2, M3, M4 for purposes of connection with the control device 2. Likewise such a charge storage module assembly B has only one common microprocessor controller 25, from which all the charge storage modules M1, M2, M3, M4 of this charge storage module assembly B are controlled. In order that the individual charge storage modules M1, M2, M3, M4 of the charge storage module assembly V are electrically insulated from one another, apart from the series connections that are provided, a signal connection to the microprocessor controller 25 is undertaken via optocouplers, which are also installed on the printed circuit board 20. Here the power capacitances of the charge storage modules M1, M2, M3, M4 are not explicitly represented.

The complete printed circuit board 20 with the four charge storage modules M1, M2, M3, M4 is accommodated in a assembly housing 21, which, as an insulating housing, consists of two plastic half shells 22a, 22b and also two end face, preferably identical, housing covers 23, 24. The assembly housing 21 is screwed together using plastic screws. The assembly housing 21 preferably has external dimensions such that it can be inserted into a 19″ standard rack.

The grouping of the charge storage modules M1, M2, M3, M4, . . . , MN into charge storage module subassemblies B, each with four charge storage modules M1, M2, M3, M4, . . . , MN has the advantage that the voltage difference within the housing 21 of a charge storage module assembly B is not too large. For example, the maximum voltage difference within the assembly housing 21 with a maximum voltage on one charge storage module M1, M2, M3, M4, . . . , MN of 1 kV is only 4 kV. On the other hand the number of light waveguide terminals and the traffic on a communications bus within the overall high-voltage switching device 1 can be lowered by the factor four. Also considerable costs can be saved as a result of the smaller number of microprocessor controllers and plug-in connections.

FIGS. 3 and 4 show the build of a charge storage module assembly B with four charge storage modules M1, M2, M3, M4 in a assembly housing 30 in accordance with a particularly preferred example of embodiment. Here the charge storage modules M1, M2, M3, M4 are built on a printed circuit board 20, as in the example of embodiment in FIG. 2.

Here, however, the assembly housing 30 consists of an inner housing part 31 and an outer housing part 34. The inner housing part 31 has on one face an opening 33, into which the printed circuit board 20 of the charge storage module assembly B is inserted. The housing walls of the inner housing part 31 consist of insulating plastic, and on their outer faces are coated with a metallisation 32a. This metallisation consists of a low-resistance conducting metal. Various coating methods are of known art to the person skilled in the art. The outer housing part 34 once again consists of two parts 34a, 34b. The first outer housing part 34a—here the larger—is made from an insulating plastic and has internal dimensions such that as a housing shell it can be slid onto the inner housing part 31, from the side opposite the opening 33 of the inner housing part 31, with as little clearance as possible. The second outer housing part 34b—here the smaller—serves as a kind of cover so as to close the opening 33 of the inner housing part 31. The dimensions of this second outer housing part 34b are matched to the first outer housing part 34a and the inner housing part 31 such that the two outer housing parts 34a, 34b can join together so as to form a closed housing part 34. The walls of the second outer housing part 34b also consist of an insulating plastic, however the inner face of this housing part 34b is provided with a metallisation 32b, which in the assembled state of the assembly housing 30 makes contact with the metallisation 32a on the outer face of the inner housing part 31.

As is easy to see from FIG. 4, the housing wall of the assembly housing 30 thus has a sandwich structure, with an inner insulating layer 36, which is formed by the wall of the inner housing part 31, and an outer insulating layer 34, which is formed by the walls of the two outer housing parts 34a, 34b, as well as a metallisation 32 arranged in between, which encloses the whole of the electronics of the charge storage module assembly B as a form of Faraday cage. The corners and edges of the assembly housing 30, i.e. of the housing parts 31, 34a, 34b are rounded (and not as schematically represented here) as far as possible so that the Faraday cage also has as far as possible only rounded structures, in order to reduce voltage peaks as far as possible.

Only on the end face with the opening 33 of the inner housing part 31 does the assembly housing 30 have no insulating layer internally. This face, which in what follows is also designated as the front face of the assembly housing 30, is provided with two electrical connecting elements 39, 40, here in the form of socket contacts, to which the two poles 4, 5 of the charge storage module assembly B are connected in the interior of the assembly housing 30, i.e. via which the poles 4, 5 of the charge storage module assembly B are led outwards, so as to connect thereto the cables for the electrical connection of the respective charge storage module assembly B with an adjacent charge storage module assembly B, or with the ground connection GV, or the high-voltage connection HVV. Here one of these electrical connecting elements 39 is electrically attached to the metallisation 32 of the assembly housing 30. This can take place directly with the passage of the one pole through the assembly housing 30. FIG. 4 shows how for this purpose the socket contact 30 at one metallisation contact point 38 is connected with the metallisation 32, for example, by soldering on a conductor of the socket contact 39. In contrast the other electrical connecting element 40 is not connected to the metallisation 32.

The overall assembly housing 30 is dimensioned such that it can be inserted into a 19″ rack.

FIG. 5 shows the build of a charge storage module assembly B with four charge storage modules M1, M2, M3, M4 in a assembly housing 50 in accordance with a further particularly preferred example of embodiment. Here too the charge storage modules M1, M2, M3, M4 are assembled on a printed circuit board 20 in exactly the same manner as in the previous examples of embodiment. Also represented here are further control boards 26 assembled on the printed circuit board 20 for the microprocessor controller, the optical coupler, etc (not represented here) and also, explicitly, power capacitances 27, of which three belong in each case to one of the charge storage modules M1, M2, M3, M4.

Here the assembly housing 50 once again consists, as in the example of embodiment in FIGS. 3 and 4, of an inner housing part 51a, 51b and an outer housing part 54a, 54b. Here the inner housing part 51a, 51b consists of an inner housing part lower part 51a and an inner housing part upper part 51b; in each case these have the form of a half shell. Here the housing walls of the inner housing part lower part 51a and the inner housing part upper part 51b also consist of an insulating plastic and on their outer faces are coated with a metallisation 52a, 52b. This metallisation 52a, 52b can once again consist of a low-resistance conducting metal.

In this assembly housing 50 the printed circuit board 20 of the charge storage module assembly B is inserted into the inner housing part lower part 51a, onto which the inner housing part upper part 51b is then attached.

The inner housing part lower part 51a has a front wall 55 on a front end face, the front face. This front wall 55 is here provided with two electrical connecting elements 39, 40, i.e. socket contacts, to which the two poles 4, 5 of the charge storage module assembly B are connected in the interior of the assembly housing 50, i.e. via which the poles 4, 5 of the charge storage module assembly B are led outwards, so as to connect the cables thereto for the electrical connection of the respective charge storage module assembly B with an adjacent charge storage module assembly B, or with the ground connection GV or the high-voltage connection HVV. In addition a plurality of small ventilation holes are located in this front wall 55, that is to say, the front wall 55 has perforated grid regions.

Moreover the inner housing part lower part 51a has on the rear end face, located opposite to the front face, a rear wall 53, which is likewise designed as a perforated grid in some regions. On this rear wall 53, at least in the region of the perforated grids, small ventilating fans 59 are arranged, which when in operation ensure that there is a good flow through the housing, so as to expel from the assembly housing 50 the waste heat generated in the charge storage module assembly B, and to avoid any overheating of components of the charge storage module assembly B. The inner housing part upper part 51b is here likewise provided with a rear wall with perforated grid regions; this is designed such that the perforated grid regions 57 of the rear wall of the inner housing part upper part 51b (not shown in the figure) coincide with the perforated grid regions 57 of the rear wall 53 of the inner housing part lower part 51a, when the inner housing part upper part 51b is fitted on the inner housing part lower part 51a.

The outer housing part once again consists of two parts 54a, 54b, each of which is designed in the form of a half shell. These outer housing parts 54a, 54b are in each case pushed from right and left over the inner housing parts 51a, 51b and are fitted into each other in approximately the central region of the inner housing part 51a, 51b (i.e. approx. above and below the longitudinal axis of the inner housing part 51a, 51b). To this end, on a bounding edge pointing towards the other housing part 54a, one of the two outer housing parts 54b has a collar section 62, into which the corresponding bounding edge of the other housing part 54a can be fitted. The outer housing parts 54a, 54b are made from an insulating plastic and have dimensions such that as housing shells they can be slid over the inner housing parts 51a, 51b with as little clearance as possible.

The outer edges 60, and thus the corners 61 of the two outer housing parts 54a, 54b also, are in each case strongly rounded. Here the rounding radius is between 10 and 20 mm.

In the two narrower sidewalls of the outer housing parts 54a, 54b, which bound on to the open faces of the outer housing parts 54a, 54b, onto which the outer housing parts 54a, 54b in each case are pushed over the inner housing parts 51a, 51b, are located in each case U-shaped recesses 63. In the assembled state of the outer housing parts 54a, 54b, slots are thereby formed externally in each case in front of the front wall 55 and the rear wall 53 of the inner sub housings 51a, 51b, so that the two electrical connecting elements 39, 40, i.e. the socket contacts, and the perforated grid regions 57 are not touched or covered by the outer housing parts 54a, 54b. Here the rounding radius of the U-base of the U-shaped recesses 63 is likewise between 10 and 20 mm.

Also in the case of this build with the inner housing parts 51a, 51b and the outer housing parts 54a, 54b, the housing wall of the assembly housing 50 has overall a sandwich structure, with an inner insulating layer, which is formed by the wall of the inner housing parts 51a, 51b, and an outer insulating layer which is formed by the walls of the two outer housing parts 54a, 54b, and also by a metallised layer 52a, 52b, arranged in between, which encloses the electronics of the charge storage module assembly B as a form of Faraday cage.

The assembly housing 50 in FIG. 5 is also dimensioned such that it can be inserted into a 19″ rack.

FIG. 6 shows the build of the charge storage module subassemblies B within the supporting frame 10 (in what follows called a rack 10, for short). The charge storage module subassemblies B are here arranged in 17 rows R, one above another, with two arranged in each row of the rack 10, i.e. the rack has two columns Sp, each with 17 such charge storage module subassemblies B, as they are represented, for example, in FIG. 3 and 4, or 5. To this end the rack 10 is divided into two parts by a central wall 17, preferably made from an insulating plastic, at least in the region of the charge storage module subassemblies B. The assembly housings 30, 50 of the charge storage module subassemblies B are in each case inserted into the rack 10 on rails 12 made of an insulating material, wherein the rails 12 are mounted internally on the sidewalls and on the central wall 17 of the rack 10. A supporting frame 10 can also be constructed in a similar manner with in each case three charge storage module subassemblies B in one row, i.e. a rack with three columns.

Here the high-voltage cabling for purposes of making the interconnections in series of the individual charge storage module subassemblies B and thus also of the charge storage modules M1, M2, M3, M4, . . . MN is undertaken with the aid of the subassemblies connection BV (i.e. the high-voltage connection) so that two charge storage module subassemblies B arranged in a row R are in each case interconnected horizontally, e.g. passing by the front of the central wall 17. At the end of a row R a horizontal connection of one of the two charge storage module subassemblies B is then undertaken with a charge storage module assembly B located directly above in the same column Sp in the rack 10. The next connection is then undertaken horizontally once again in the same row R, and then vertically upwards once again in the adjacent column Sp, and so on. Ultimately, therefore, all charge storage module subassemblies B are interconnected in a serpentine pattern within the rack 10. The first lowest charge storage module assembly B (in FIG. 3 the left-hand lower charge storage module assembly B) is connected via the ground connection GV with the ground potential that is present. The last charge storage module assembly B of the charge storage arrangement 3 (here the charge storage module assembly B on the right-hand side at the top) is connected to the free pole via the high-voltage connection HVV and via the switches S1, S2 with each of the terminals E1, A1 (not represented in FIG. 3, on this point see the block circuit diagram in FIG. 1).

The rack 10 is provided with a housing 11, which is of a multi-layer sandwich form of construction. Here some layers 13, 15 are designed so as to be conducting, for example in the form of metal sheets; for purposes of forming a stable housing 11, i.e. supporting frame 10, these are mechanically connected with one another at the edges in an electrically conducting manner by means of framework parts (not represented). Other layers 14, 16 serve as insulating layers 14, 16, wherein one of the layers takes the form of a cavity layer 14 (between the metal layers 13, 15) and another insulating layer 16, located innermost, takes the form of plastic with a thickness of at least 4 mm, preferably 10 mm. Here, however, it is not necessary for a conducting layer always to alternate exactly with a non-conducting layer, rather the non-conducting layer can, for example, be implemented from a plurality of non-conducting layers such as cavities and plastic coatings on the metal sheets, etc. This multi-layer sandwich structure ensures that the overall charge storage arrangement 3 is enclosed in a plurality of Faraday cages that enclose one another, so as to achieve the highest possible level of safety for operating personnel who can move in the vicinity of the housing 11 during operations.

Here diode stacks are arranged above the charge storage arrangement 3 inside the rack 10, i.e. the housing 11; these implement the switches S1, S2. Moreover other components of the high-voltage switching device can also be arranged in the rack 10, i.e. housing 11, such as, for example, the controller 2. The whole rack 10 is mounted on feet 18, so as to ensure a separation distance from the floor.

The housing 11 is here designed to be air-tight and filled with an inert gas, e.g. nitrogen, so as to increase the dielectric strength between the charge storage module subassemblies. The assembly housings 30, 50 are not in themselves sealed, so that the charge of inert gas is also present in the interior of the assembly housings 30, 50. If required, extra holes can also be introduced, or ventilator fans 59 (see FIG. 5) can even be arranged, in the assembly housing 30, 50 (not represented in FIGS. 3 and 4), so that there is a better passage of gas through the assembly housing 30, 50. This applies to all forms of assembly housings. By means of heat exchangers (not represented) cooling of the gas and thus of the overall charge storage arrangement 3 is ensured. Since no intermediate floors are required between the individual charge storage module subassemblies B, a simple fan within the housing 11 is sufficient to ensure that gas flows around each of the charge storage module subassemblies B such that each is effectively cooled. If field strength peaks nevertheless occur, these are blown away by the gas that flows past them.

The charge storage module subassemblies B are built such that electrical connections are made solely from the front. From the front they can simply be plugged in and also pulled out once again. The rear wall of the housing can accordingly be permanently closed ex factory. This increases reliability and imparts more degrees of freedom to the installation, since access from the rear is no longer necessary. Here ventilation can advantageously be directed into the rear part of the rack.

By the particular build of the charge storage module subassemblies B in each case as a group of four with an independent assembly housing 21, 30, 50 and the particular arrangement and serpentine interconnections of the charge storage module subassemblies B within the rack 10, a maximum differential voltage of 16 kV is present between two assembly housings 21, 30, 50 arranged one above another when using 1 kV charge storage modules. By virtue of the insulating housing 21, 30, 50 and the insulated mounting in the rails 15 with this maximum voltage difference a separation distance d, between the upper edge of a lower charge storage module assembly B and the lower edge of a charge storage module assembly B arranged above, of approx. 20 to 30 mm is sufficient to ensure a sufficient dielectric strength.

With the aid of FIG. 7 the advantage of the special assembly housing 30 with a metallisation 32 can also once again be seen; this metallisation is connected in each case to one of the two poles 4, 5 of the charge storage module assembly B. Here four charge storage module subassemblies B are shown, in each case with four charge storage modules M1, M2, M3, M4, M5, M6, M7, M8, M9, M10, M11, M12, M13, M14, M15, M16, accommodated in such a assembly housing 30, wherein the charge storage module subassemblies B are arranged in each case in two rows one above another and are electrically connected with one another in a serpentine pattern, as is the case in the build in accordance with FIG. 6.

In the example in FIG. 7 in each case the pole 4 lying at lower potential is thereby connected to a metallisation contact point 38 with the metallisation 32. That is to say, the Faraday cage, which surrounds the electronics of the charge storage module assembly B, always lies at this input potential of the charge storage module assembly B. As a consequence the maximum potential difference between an electronic component of a charge storage module M1, M2, M3, M4, M5, M6, M7, M8, M9, M10, M11, M12, M13, M14, M15, M16, for example, of the charge storage module M4, M8, M12, M16 in each case lying next to the output pole 5 also cannot be larger than the maximum potential difference between the poles 4, 5, i.e. here 4 kV. The overall charge storage module assembly B is thus located at a jumping potential, wherein, however, the components of the charge storage module assembly B are screened by the metallisation 32 from greater potential differences, for example to the housing 11 of the rack 10, Thus the electronics of the charge storage module subassemblies B are protected to a large extent against displacement currents.

FIG. 8 shows a somewhat different variant for purposes of connecting the metallisation 52 of the assembly housing 50 with a metallisation contact point 58 within the charge storage module assembly B located in the assembly housing 50. This example relates here in particular to the build of the assembly housing 50 in accordance with FIG. 5, i.e. the assembly housing 50 here has an inner insulating layer 56, which is implemented by the inner wall of the inner housing parts 51a, 51b, as well as a metallisation 52 located on it externally at the sides, which in turn is electrically insulated outwardly by the outer housing parts 54a, 54b. However, the special form of contact with the metallisation 52 is not limited to this particular type of assembly housing 50, i.e. the contact of the metallisation 32, 52 in FIGS. 7 and 8 is independent of the particular build of the assembly housing 30, 50.

In this example of embodiment in FIG. 8 the metallisation 52 of the assembly housing 50 is connected with a metallisation contact point 58 between the two central charge storage modules M2, M3 of the charge storage module assembly B. Thus the metallisation 52 (and thus the Faraday cage, which surrounds the electronics of the charge storage module assembly B), lies at the average voltage potential of the charge storage module assembly B. As a consequence in this example of embodiment the maximum potential difference between an electronic component of a charge storage module M1, M2, M3, M4, M5, M6, M7, M8, M9, M10, M11, M12, M13, M14, M15, M16, for example of the charge storage module M4, M8, M12, M16 in each case lying next to one of the poles 4, 5, cannot be greater than half the maximum potential difference between the poles 4, 5, i.e. here 2 kV.

By means of a horizontal arrangement of the assembly housings 21, 30, 50 it is moreover achieved that the capacitance between the assembly housings 21, 30, 50 and the rack 10, between which the voltage difference in operation is greater than between two modular subassemblies, is reduced. By this means the displacement currents are smaller.

Moreover this build of the assembly housing 21, 30, 50 has the advantage that between two charge storage module subassemblies B arranged side-by-side, or one above another, in the rack 10 an electrical field strength, to some extent defined, is present and here no extreme corners and edges lying at greatly different potentials are present, on which particularly strong field strength peaks can form, which could lead to a spark flashover. In particular a build of the assembly housing 50, as in FIG. 5, with strongly rounded corners and edges can support this further.

As the present example of embodiment shows, the invention allows a relatively simple build with a simple high-voltage cabling with only short cabling paths. The modular form of construction enables moreover a very simple form of scaling. If a higher voltage is required, two further charge storage module subassemblies B can simply be inserted. If necessary a taller rack can be used. The height is (in the case of a vertical build as in FIG. 5) simply limited by the room height available. Advantageously such a structure is deployed for a high-voltage switching device with a multiplicity of charge storage module subassemblies B. An inventive high-voltage switching device preferably has therefore at least 10 rows of charge storage module subassemblies B. In the event of a defect of a charge storage module it is simply necessary to replace a charge storage module assembly B and the overall high-voltage switching device is immediately once again ready for operations, while the charge storage module assembly B that was replaced can be subjected to a repair.

In conclusion it should once again be emphasised that the above described high-voltage switching device takes the form of just one example of embodiment, which can be modified in a wide variety of ways by the person skilled in the art within the framework of the claims, without straying outside the scope of the invention. In particular the inventive high-voltage switching devices can also be deployed for other purposes, in which particularly high voltages, in particular short voltage pulses with more than 100 kV and relatively high currents of 10 A, or a multiple of the latter, are used, even though the above applications are described using the example of a klystron, and the application to klystrons and kicker magnets is particularly relevant. Furthermore the use of the indefinite article “a” or “an” does not exclude the fact that the features concerned can also be present in multiple form.

1. A high-voltage switching device (1) with a charge storage arrangement (3) with a multiplicity of charge storage modules (M1, M2, M3, M4, . . . , MN) connected in series, wherein in each case a certain number of the charge storage modules (M1, M2, M3, M4, . . . , MN) are arranged in a common assembly housing (21, 30, 50) so as to form a charge storage module assembly (B), and wherein the assembly housings (21, 30, 50) are mounted in an insulated manner in a supporting frame (10).

2. The high-voltage switching device in accordance with claim 1, characterised in that at least one assembly housing (30, 50) has a conducting structure enclosing the charge storage module assembly (B) as a Faraday cage.

3. The high-voltage switching device in accordance with claim 1 or 2, characterised in that each charge storage module (M1, M2, M3, M4, . . . , MN), each charge storage module assembly (B), and the charge storage arrangement (3), are of a 2-pole design.

4. The high-voltage switching device in accordance with claims 2 and 3, characterised in that a charge storage module assembly (B), preferably of one of the two poles (4, 5) or a contact point (58) of the charge storage module assembly (B), located at an average potential within the charge storage module assembly (B), is electrically connected with the conducting structure (32, 52).

5. The high-voltage switching device in accordance with one of the claims 1 to 4, characterised in that at least one assembly housing (21, 30, 50) has an insulating layer (34, 36, 56) on an outer face of the housing, and/or on an inner face of the housing.

6. The high-voltage switching device in accordance with one of the claims 1 to 5, characterised in that a assembly housing (30, 50) has at least one inner housing part (31, 51a, 51b) and one outer housing part (34a, 34b, 54a, 54b) at least partly enclosing the inner housing part (31, 51a, 51b), so as to form a multi-layer housing.

7. The high-voltage switching device in accordance with one of the claims 1 to 6, characterised in that on at least one outer face of a assembly housing (50) any edges (60) and corners (61) are rounded, and preferably have a rounding radius of at least 10 mm.

8. The high-voltage switching device in accordance with one of the claims 1 to 7, characterised in that the charge storage modules (M) of a charge storage module assembly (B) are arranged on a common assembly support (20).

9. The high-voltage switching device in accordance with one of the claims 1 to 8, characterised in that in each case a number of, preferably two or three, charge storage module subassemblies (B) are adjacently arranged in a row in the supporting frame (10) and are electrically interconnected, and the electrical connection from one row (R) to an adjacently arranged row (R) of charge storage module subassemblies (B) is undertaken in each case between two directly adjacently arranged charge storage module subassemblies (B) of the two rows (R).

10. The high-voltage switching device in accordance with claim 9, characterised in that the rows (R) of the charge storage module assemblies (B) are arranged one above another in the supporting frame (10).

11. The high-voltage switching device in accordance with one of the claims 1 to 10, characterised in that a charge storage module (M1, M2, M3, M4, . . . , MN) is designed such that in operation a maximum voltage difference of 2 kV, preferably a maximum of 1 kV, is present between its two poles.

12. The high-voltage switching device in accordance with one of the claims 1 to 11, characterised in that a charge storage module assembly (B) comprises a maximum of eight, preferably a maximum of four, charge storage modules ((M1, M2, M3, M4, . . . , MN).

13. The high-voltage switching device in accordance with one of the claims 1 to 12, characterised by a housing (11) surrounding at least the charge storage arrangement (B), which is built in a sandwich form of construction with electrically insulating layers (16) and with electrically conducting layers (13, 15).

14. The high-voltage switching device in accordance with claim 13, characterised in that the housing (11) is filled with a fluid, preferably a gas, which has an increased dielectric strength.

15. The high-voltage switching device in accordance with one of the claims 1 to 14, characterised in that the charge storage modules (M1, M2, M3, M4, . . . , MN) are connected in series via at least one first switch (S1) with two input terminals (E1, E2), and via at least one second switch (S2) with two output terminals (A1, A2), wherein in operation an input voltage (UE) is present at the input terminals (E1, E2), and the output terminals (A1, A2) are connected with high-voltage terminal contacts of the high-energy functional component (6),
and in that the high-voltage switching device has a control device (2) for purposes of controlling the individual charge storage modules (M1, M2, M3, M4, . . . , MN) and the first and second switches (S1, S2), and the charge storage modules (M1, M2, M3, M4, . . . , MN) and the control device (2) are designed such that in a charging phase the first switch (S1) is closed and the charge storage modules (M1, M2, M3, M4, . . . , MN) individually, or as a group, are successively connected in series with a charging voltage, then in a discharging phase the first switch (S1) is opened and the charge storage modules (M1, M2, M3, M4, . . . , MN) are disconnected from the charging voltage, and the second switch (S2) is closed and at least a proportion of the charge storage modules (M1, M2, M3, M4, . . ., MN) are discharged with the delivery of a voltage pulse onto the high-energy functional component (6).

16. The use of a high-voltage switching device (1) in accordance with one of the claims 1 to 15, for purposes of supplying a high-energy functional component (6), preferably a klystron (6) or kicker magnets, with high-voltage pulses.
